(19) United States
(12) Patent Application Publication
(10) Pub. No.: US 2013/0054153 A1
(43) Pub. Date: Feb. 28, 2013

(54) METHOD AND APPARATUS FOR MATERIAL ANALYSIS BY A FOCUSED ELECTRON BEAM USING CHARACTERISTIC X-RAYS AND BACK-SCATTERED ELECTRONS

(71) Applicants: David MOTL, Brno (CZ); Vojtech FILIP, Brno (CZ)

(72) Inventors: David MOTL, Brno (CZ); Vojtech FILIP, Brno (CZ)

(73) Assignee: TESCAN, a.s., Brno (CZ)

(21) Appl. No.: 13/398,114

(22) Filed: Feb. 16, 2012

(30) Foreign Application Priority Data
Mar. 23, 2011 (CZ) 2011-154

(51) Int. Cl. G06F 19/00; H01J 37/29; G01N 23/22

(52) U.S. Cl. 702/28

(57) ABSTRACT

A material analysis method by a focused electron beam and an equipment for performing such an analysis where an electron map B is created describing the intensity of emitted back-scattered electrons at various points on a sample, and a spectral map S is created describing the intensity of emitted X-rays at points on the sample depending on the radiation energy. For selected chemical elements, X-ray maps Mᵢ are created representing the intensity of X-rays characteristic for such elements. The X-ray maps Mᵢ and the electron map B are converted into differential X-ray maps Dᵢ, which are subsequently merged into a final differential X-ray map D. The final differential X-ray map D is then used to search particles. Subsequently, a cumulative X-ray spectrum Xⱼ is calculated for each particle and subsequently the classification of particles based on the peak intensities and the intensity of back-scattered electron is performed.

### FIELD OF INVENTION

The present invention relates to a method and apparatus for material analysis by a focused electron beam using characteristic X-rays and back-scattered electrons.

The proposed solution facilitates the identification and analysis of non-homogeneous materials. The term “particles” refers to the continuous spatially delimited areas on a sample surface, which in terms of the detecting abilities of the equipment seem homogeneous. “Morphological analysis of particles” refers to the determination of their morphological properties, such as shape or area. “Qualitative and quantitative spectroscopic analysis” are analytical chemistry methods which enable one to establish the presence of chemical elements contained in the assayed substance and their percentages therein, based on examining characteristic X-rays. The presented method is especially suitable in the analysis of the relationships between the individual types of materials contained in the examined sample.

### BACKGROUND OF THE INVENTION

The spectroscopic analysis using characteristic X-rays generated during an interaction of a focused beam of accelerated electrons which impact on the surface of an assayed sample with mass situated close to the surface of the assayed sample is an important tool for the study of the chemical and physical properties of materials. The analysis is performed in a scanning electron microscope 13, see FIG. 1. The electron microscope 13 creates in an electron gun 1 a beam of accelerated electrons 2, which is deflected using a pair of deflecting coils 3 so that it impacts consecutively on an assayed sample 4 at various points. The currents through the deflecting coils 3 are controlled by scanning circuits 5 that generate a deflecting signal following predefined instructions, most often in a regular rectangular grid. After the impact of the accelerated electrons on the surface of the sample 4, interactions are initiated between the impinging electrons and the material, which is situated close to the surface of the sample. During the interactions between the accelerated electrons and the material, several types of products result of which two are particularly important for the study of the chemical properties of the materials: back-scattered electrons 6, abbreviated as BSE, and X-ray radiation 7.

The back-scattered electrons are the electrons of the impinging beam which, after elastic collisions with the atoms of the material, leave the sample with a relatively small loss of energy compared to the energy with which they impacted on the sample. The probability of an elastic collision occurring depends strongly on the atomic number Z of the material. The back-scattered electrons may continue on to various types of interaction with other atoms in their surroundings, until finally some of them leave the material. The interactions happen within a given volume underneath the surface of the sample in the so-called interaction volume. The ratio of the number of electrons impinging on the surface of the sample to the number of electrons leaving the sample again with a roughly similar energy is called the back-scatter coefficient, marked as η in the literature. This variable is also dependent on the atomic number Z. In materials composed of multiple chemical elements the following equation published by Kurt F. J. Heinrich in the Proceedings of the 4^{th} International Conference on X-ray Optics and Microanalysis in 1966 applies.

$$η = {Σ}_{i} {C}_{i} {η}_{i}$$

where η is the back-scatter coefficient in the composite material, Cᵢ is the mass concentration of the element i and ηᵢ is the back-scatter coefficient of a material composed of only the element i. The intensity of the back-scattered electrons is measured using a detector 8 of the back-scattered electrons: the analog signal from the detector 8 of the back-scattered electrons is converted into a digital format using an analog-to-digital converter 9, and based on information from its output, an image representing the distribution of the intensity of the back-scattered electrons at the points on the sample is created in the computer memory.

Energy-dispersive X-ray spectroscopy, abbreviated as EDS, is one of the methods for studying the chemical properties of materials using characteristic X-rays, which is another by-product of the interaction between the accelerated electrons and the sample material. Electrons in the atom occur in the electron cloud. The state of the electrons in the atoms cannot be random as an electron must be in a discrete state. The state of an electron is described using four quantum numbers. The kinetic energy of an electron is determined by which atomic orbital of which atom the electron occurs in. In the ground state, following the Aufbau principle, the electrons in the cloud are arranged so that they hold a position in orbitals with the lowest energy, whereby only two electrons may occupy a single orbital. An accelerated electron of the beam impinging on the sample has sufficient kinetic energy in order to transfer, with a certain probability, part of its kinetic energy to one of the electrons situated in one of the orbitals. The excited electron will leave the orbital, leaving an empty space behind. In a very short time, of the order of picoseconds, the atom will return to the ground state, as one of the electrons from an orbital with higher energy will fill the emptied space, and simultaneously release part of its binding energy in the form of a photon of electromagnetic X-ray radiation. The orbitals being discrete, the energy of the generated photon cannot be random, but corresponds to the difference between the energy of the orbital where the electron originally occurred and the energy of the orbital where an empty space was created during the interaction. The energy of the atomic orbital is unique for each chemical element and, as a result, each element exposed to a beam of accelerated electrons emits photons with energies which are characteristic of that particular element. This radiation is therefore called characteristic X-rays. The photons of the X-ray radiation undergo further interactions with the material; some of them leave the material and can be intercepted by an X-ray radiation detector. EDS uses an energy-dispersive detector 10 of X-ray radiation where the voltage at its output changes after an X-ray photon has impacted on its active surface and the magnitude of the change in voltage is proportionate to the photon energy. A pulse processor 11 is an electronic device that converts an analog signal from the output of the energy-dispersive detector 10 of X-ray radiation to digital format. Based on these reports, a histogram, referred to as a spectrum, is created in a computer memory, expressing the number of detected photons, the energy of which falls within predefined narrow intervals. As has been mentioned, the X-ray radiation photons arising in the material are characteristic for the element or elements contained within, and the frequency of the detection of photons with characteristic energies is therefore higher than that of the other photons. As a result, the energy-dispersive spectrum contains emission lines corresponding with the chemical elements contained in the sample. When the material is not homogeneous, it should be taken into account that radiation is again generated within a particular interaction volume underneath the surface of the sample, which is generally larger than the interaction volume, in which the back-scattered electrons originate. This effect is especially significant when the electron beam impacts on an interface of multiple areas with different chemical composition. In this case, the observed X-ray radiation corresponds to the combination of the spectra from those areas.

Quantitative spectroscopic analysis is a method of analytical chemistry for determining the percentages of chemical elements contained in the assayed substance based on examining characteristic X-rays. The analysis using the energy-dispersive spectrum is based on the relation between the intensity of X-ray radiation having energy characteristic for an element, further referred to as peak intensity, to the mass fraction of this element in an assayed substance. It was shown by Raimond Castaing in 1951 that the generated primary intensities are roughly proportional to the respective mass fractions of the emitting element. In the quantitative spectroscopic analysis, the ratio between peak intensities generated in an assayed substance and peak intensities generated in a substance of known composition is utilized. The ratio between peak intensities generated in an unknown substance and in a substance of known composition is in the literature referred to as the k-ratio. To get percentages of chemical elements contained in the assayed substance, the calculated k-ratios are subjected to corrections describing the level of absorption and repeated emission (fluorescence) of X-ray radiation, collectively referred to in literature as ZAF corrections. In order to simplify the calculation, it is usually assumed in the analysis that examined materials are homogeneous.

In analyzing non-homogeneous materials, the technique employed is usually referred to in the literature as X-ray mapping. The mapping is usually performed by consecutively deflecting the electron beam to various points on the sample. A control unit 12 ensures the synchronization of the circuits for the beam deflection and the pulse processor 11. The synchronization facilitates locating the spot on the sample from which the detected X-ray radiation originates. In this way, it is possible to obtain spectroscopic X-ray data with spatial differentiation. The simplest X-ray mapping technique is a method known as dot mapping. In this method, the interval of X-ray radiation energies is set in advance. The mapping result is displayed in the form of a two-dimensional bi-level image, in which the black and the white points indicate the spots on the sample where the number of detected events per unit of time falling within the predefined energy interval is higher and lower than a predefined threshold respectively. More elaborate information on the chemical composition of heterogeneous samples is provided by the technique known as gray-scale mapping. The mapping result is displayed in the form of a two-dimensional gray-scale image, in which the gray level of each point is proportional to the number of detected events per unit of time falling within the predefined energy interval. A precondition of using gray-scale mapping is sufficient spectroscopic data. This precondition is not easy to meet as the signal from the EDS detector is relatively weak relative to the resolution of the maps used in the particle analysis.

A key component of an automated particle spectroscopic analyzer based on gray-scale mapping is image segmentation. In computer graphics, image segmentation refers to a set of techniques for image division into separate areas. In the past, a number of techniques for image segmentation were published. Some of the published methods are based on transformation which in the literature is described with the term “watershed.” The original idea was presented by Serge Beucher and Christian Lantuéjoul in the article “Use of watersheds in contour detection” published in September 1979 in the proceedings of the International Workshop on Image Processing in Rennes. The transformation is based on the idea that a single-channel (gray-scale) image can be thought of as a topographic relief, where the value of a point in the image correlates with the point elevation above the zero plane. The relief is gradually flooded with water. In the low-lying places, corresponding with the local minimum values, pools of water are formed. Where the pools would flow together, a dike is built between them. The result of the procedure is an image divided up into continuous areas which form in places where, in the input image, the values are lower than in the surroundings. From the previous text, it is obvious that the watershed transformation input is a single-channel differential image where the pixel values correspond to the magnitude of the gradient in the original image as in those places the watershed transformation creates boundaries between the areas. An extension of this method to the application of conversion to a multi-channel image can be found, for example, in the contribution “A Multichannel Watershed-Based Segmentation Method for Multispectral Chromosome Classification” published by Petros S. Karvelis in the IEEE Transactions on Medical Imaging, Volume 27, No. 5, where this technology is used for the classification of chromosomes in an image obtained using a multi-channel fluorescence imaging method.

Prior to the image segmentation using the watershed transformation, another transformation, called edge detection, is employed. The purpose is to transform the input image so that, at the spot with a transition between two areas with different intensity, the values in the output image are higher than in the surrounding points. Most of the edge detection algorithms are based on the gradient operator ∇ from the vector calculus. The gradient of a scalar field is a vector field which points in the direction of the greatest rate of increase of the scalar field and its magnitude is that rate of increase. The single-channel image can be thought of as a scalar function I=I(x, y): R²→R. The gradient operator ∇ applied to the scalar function I is defined as follows:

$$∇ I = {( \frac{\partial I}{\partial x} \frac{\partial I}{\partial y} )}^{T} = {( {I}_{x} {I}_{y} )}^{T}$$

The magnitude of the rate of change H(x, y) of the function I at a point with coordinates x and y can be derived as the Euclidean norm of the vector ∇I(x, y). Therefore, the resulting scalar function H=H(x, y): R²→R can be derived as follows:

H=∥∇I∥=\sqrt{Iₓ²+I_{y}²}

One of the frequently used implementation of this paradigm is referred to in the literature as the Sobel operator. It can be proven that the edge detection in a single-channel (gray-scale) image can be carried out using two convolutions of the original image I with matrix Fₓ and F_{y}.

$${F}_{x} = ( \begin{matrix}- 1 & - 2 & - 1 \\ 0 & 0 & 0 \\ + 1 & + 2 & + 1\end{matrix} )$$

$${F}_{y} = ( \begin{matrix}+ 1 & 0 & - 1 \\ + 2 & 0 & - 2 \\ + 1 & 0 & - 1\end{matrix} )$$

The result of the convolution of an image I and matrix Fₓ and F_{y} is a vector field G, which consists of two components Gₓ and G_{y}. The output image H, which contains the magnitude of a vector field G, is computed as follows:

Gₓ=I*Fₓ G_{y}=I*F_{y} H=\sqrt{Gₓ²+G_{y}²}

In material analysis based on X-ray mapping, it is beneficial to use information obtained from both types of detector. The interaction volume of the back-scattered electrons is generally smaller than the interaction volume of the X-ray radiation; the boundaries between particles are therefore better defined in the back-scatter electron image than in an image created exclusively from X-ray data. On the contrary, if the image segmentation is only based on an image from the BSE detector, the equipment is not able to detect a boundary between two materials which have a very close value of back-scatter coefficient n, as these materials cannot be distinguished only based on comparing the intensity level of the back-scattered electrons. As was stated before, the Sobel operator can be applied to a single-channel image only. An extension of this concept to multi-channel images was published in 1994 by Christian Drewniok in his paper “Multi-Spectral Edge Detection—some experiments on data from Landsat™”. He showed that although the gradient operator per se only applies to scalar functions, the idea can be easily extended to multi-dimensional functions. He has demonstrated a gradient-based approach for detecting edges in multi-channel images and its application in multi-spectral satellite imagery.

A multi-channel image can be thought of as a vector function C=C(x, y): R²→Rⁿ, where n is a number of channels. The gradient of the function C in a direction \vec{n} is defined as follows:

$$\frac{\partial C}{\partial \vec{n}} = {( \frac{\partial {C}_{1}}{\partial \vec{n}} … \frac{\partial {C}_{n}}{\partial \vec{n}} )}^{T} = J . \vec{n}$$

The matrix J is the Jacobian matrix of the vector function C. The magnitude of change of C can be derived as Euclidean norm of the vector J·\vec{n} in direction of maximum value of change.

l²(\vec{n})=∥J·\vec{n}∥=\vec{n}^{T}·(J·J^{T})·\vec{n}

It can be proven, that the problem of maximizing the norm l²(\vec{n}) as a function of \vec{n} can be solved as computing the maximum eigenvalue of the matrix J·J^{T}. The magnitude of change of C is equal to the maximum eigenvalue λₘₐₓ.

$${a}_{11} = {( \frac{\partial {C}_{1}}{\partial x} )}^{2} + … + {( \frac{\partial {C}_{n}}{\partial x} )}^{2}$$

$${a}_{22} = {( \frac{\partial {C}_{1}}{\partial y} )}^{2} + … + {( \frac{\partial {C}_{n}}{\partial y} )}^{2}$$

$${a}_{12} = ( \frac{\partial {C}_{1}}{\partial x} \frac{\partial {C}_{1}}{\partial y} ) + … + ( \frac{\partial {C}_{n}}{\partial x} \frac{\partial {C}_{n}}{\partial y} )$$

The values a₁₁, a₁₂ and a₂₂ are defined by means of the first-order partial derivatives of the function C as follows:

$${λ}_{max} = \frac{1}{2} ( ( {a}_{11} + {a}_{22} ) + \sqrt{{( {a}_{11} - {a}_{22} )}^{2} + 4 {a}_{12}^{2}} )$$

The analysis of non-homogeneous materials in a screening electron microscope is dealt with, for example, in U.S. Pat. No. 7,490,009. The described equipment collects spectroscopic data using an energy-dispersive spectrometer. By comparing the acquired data with a predefined set of spectral categories, the equipment first assigns the individual measuring points to the pre-defined spectral categories. Based on these categories continuous groups of points are subsequently created and, from them, particles. The disadvantage of this solution is the necessity to define a great number of spectral categories as owing to the size of the interaction volume for X-ray radiation which is comparable with the distance of the adjacent measuring points, there is emission of X-ray radiation in both particles in the vicinity of the interface of two particles. As a result, spectroscopic data is distorted in this case while the detected characteristic X-rays originate at this point from two chemically different materials, and correct classification is difficult in this case. In addition, proper classification requires that sufficient data is collected in each measuring point which is demanding in terms of time. Another disadvantage of the equipment is the fact that the detection of particles is based on a classification made using spectral data and ignores information from the detector of the back-scattered electrons.

### SUMMARY AND ADVANTAGES

The disadvantages described above are eliminated by the method of material analysis using a focused electron beam in a scanning electron microscope and the equipment to perform it. In a preferred embodiment, the method starts by establishing, using an expert estimate, an adequately large set P of chemical elements, further as set P, which might occur in the assayed sample. For each element pᵢ from set P the interval Iᵢ of energies of X-ray photons is determined corresponding to one of the emission lines of the element. Next, the focused electron beam is consecutively deflected to points on the assayed sample and at the points the intensity of the back-scattered electrons is established for the purpose of creating an electron map B and a histogram of the energies of the X-ray radiation emitted in this point is established with the purpose of creating a spectral map S. A significant feature of a preferred embodiment of the new method consists in the fact that a X-ray map Mᵢ is created for each element pᵢ from set P where the values Mᵢ(x, y) stored in the map Mᵢ are related to the points on the sample with coordinates (x, y) and correlate with the intensity of X-ray radiation with energy within the interval Iᵢ emitted in these points. Afterwards, the multi-channel gradient algorithm is applied to the X-ray maps Mᵢ and the electron map B to create a differential map D, where the values D(x, y) stored in the map D are related to the points on the sample with coordinates (x, y) and correlate with the magnitude of the intensity gradient of the back-scattered electrons and the magnitude of the intensity gradient of X-ray radiation with energy within intervals Iᵢ for all elements pᵢ from set P. This is followed by the image segmentation, using watershed transformation applied to the differential map D, in order to search for particles. The result of this operation is a set Q of particles, further as set Q, where each particle is assigned a sequence number j, and a map R of particle distribution, where the values R(x, y) stored in map R are related to the points on the sample with coordinates (x, y) and correlate with the sequence number of the particle. Using an expert estimate, the value of coefficient a is set, which value influences the weight of the border points in a weighted mean, and by using the weighted mean, for each particle qⱼ from set Q, spectrum Xⱼ of X-ray radiation is determined from spectral map S using the coefficient a, where the values Xⱼ(E) stored in Xⱼ are accumulated intensities of X-ray radiation with energy E. In the end, peak intensities N_{i,j} are computed as a total number of X-ray events recorded in spectrum Xⱼ with energy within intervals Iᵢ for all elements pᵢ from set P and for all particles qⱼ from set Q.

The gradient-based edge detection in multi-channel imagery can be realized using an algorithm that comprises the following steps. The input of the algorithm is a multi-channel image M that consists of n channels. The output is a single-channel gradient image H, where values H(x, y) at a point with coordinates x and y correspond to a magnitude of change of image M at that point. Initially, the values of matrices Fₓ and F_{y} are computed as the first-order partial derivatives of the discrete two-dimensional Gaussian function G(x, y, x₀, y₀, σ). The Gaussian function is centered to the central element of matrices and its width, the parameter σ, is set by an expert estimate based on the ratio of size of interaction volume in material of an assayed sample and known distance between two adjacent measurement spots.

$${F}_{x} = \frac{\partial }{\partial x} G ( x , y )$$

$${F}_{y} = \frac{\partial }{\partial y} G ( x , y )$$

Then, two partial derivatives Gᵢ^{x} and Gᵢ^{y} for the channel i and directions x and y are derived by two convolutions of channel Mᵢ of the image M with matrices Fₓ and F_{y} respectively.

Gᵢ^{x}=Mᵢ*Fₓ Gᵢ^{y}=Mᵢ*F_{y}

In a subsequent step, the values Gᵢ^{x} and Gᵢ^{y} are summed together for all channels i from 1 to n, to get the values a₁₁, a₁₂ and a₂₂.

$${a}_{11} = {\sum }_{i = 1}^{n} {( {G}_{i}^{x} )}^{2}$$

$${a}_{22} = {\sum }_{i = 1}^{n} {( {G}_{i}^{y} )}^{2}$$

$${a}_{12} = {\sum }_{i = 1}^{n} {G}_{i}^{x} {G}_{i}^{y}$$

The value H(x, y) of resulting gradient image D is computed as the value of maximum eigenvalue λₘₐₓ:

$$D = {λ}_{max} = \frac{1}{2} ( ( {a}_{11} + {a}_{22} ) + \sqrt{{( {a}_{11} - {a}_{22} )}^{2} + 4 {a}_{12}^{2}} )$$

Another alternative preferred embodiment comprises using an expert estimate to set the values of coefficients bₘᵢₙ and bₘₐₓ, which values represent the minimum and maximum expected level of intensity of the back-scattered electrons in materials which are the subject of the performed analysis. In the next step, the mean level of intensity of the back-scattered electrons bⱼ is determined for each particle qⱼ from the set Q based on the map R of particle distribution and the electron map B using the median. If value bⱼ is situated within the closed interval between values bₘᵢₙ and bₘₐₓ, particle qⱼ is inserted in a new set Q′. Then, the spectrum Xⱼ of X-ray radiation is established for each particle qⱼ from the new set Q′ using a weighted mean from spectral map S using the coefficient a. Peak intensities N_{i,j} are subsequently computed as a total number of X-ray events recorded in spectrum Xⱼ with energy within intervals Iᵢ for all elements pᵢ from set P and for all particles qⱼ from set Q.

Yet another alternative preferred embodiment comprises using an expert estimate to specify a set Z of rules for classification, further as set Z, being a totally ordered set of pairs (cₖ, vₖ) and each class cₖ is assigned a logical expression vₖ consisting of identifiers of variables, arithmetic operators, logical operators, comparison operators and numerical constants. Next, a set of variables occurring in expressions stored in set Z is determined. For each particle qⱼ from the set Q the peak intensities N_{i,j} are assigned to these variables which is followed by evaluating the logical value of expressions in order of their appearance in the set Z. The evaluation is stopped on one of the following two conditions: a) an expression that evaluates to “true” is found or b) all expressions are evaluated to “false”. In case the evaluation has been finished on the first condition, the first class from the top of the list Z whose expression is true is assigned to a set Cⱼ, being a result of classification of particle qⱼ. In case of stopping on the second condition, where all expressions are false, the result of the classification of particle qⱼ is an empty set Cⱼ. This method can also be applied to the case described in the previous paragraph; in this case the mean level of intensity of back-scattered electrons bⱼ is also assigned to a variable occurring in the expressions.

The equipment for performing the method following the basic procedure is based on equipment comprising a scanning electron microscope equipped with a detector of back-scattered electrons connected to the input of an analog-to-digital converter and an energy-dispersion detector of X-ray radiation connected to the input of a pulse processor. The output of the analog-to-digital converter and the output of the pulse processor are connected to a processing unit. The whole processing unit is preceded by a data storage unit that contains processing instructions (program) and a memory unit for storing data during analysis and results of the analysis. The processing unit is also preceded by an input device for entering the input values, a pointing device for marking the selected particles and a display device for displaying results of the analysis.

Advantages of the preferred embodiments of the method and equipment include the following: Particle search uses back-scattered electrons. Due to the small interaction volume for back-scattered electrons, the boundaries between particles are better defined. It is therefore possible to analyze smaller particles with a lower error than in searching for particles only based on X-ray data. The particle search also uses X-ray radiation which enables reliable detection of the boundary between two materials, which may have different chemical composition, but a similar value of the emissivity of the back-scattered electrons. Another advantage is the fact that it is the particles that are classified instead of the individual points. This approach facilitates better handling of marginal phenomena occurring close to the transition between two particles with different chemical composition thanks to the non-negligible size of the interactive volume for X-ray radiation, which significantly reduces the number of necessary classification classes. Also the time demands of the whole analysis are considerably reduced due to the lower number of classifications. The demands on time of the analysis can be reduced even further when the assayed sample contains a considerable number of particles which from the point of view of the analysis performed are uninteresting and can be excluded before the quantitative spectroscopic analysis based on the intensity of the back-scattered electrons. A typical example is carbon powder, which is added to mineralogical samples in order to simplify the particle analysis as it reduces the probability of contact between particles. Carbon has a significantly lower BSE emissivity than other materials, which are usually subject to analysis. Using the comparative block it is possible to exclude particles containing only pure carbon from further processing.

### BRIEF DESCRIPTION OF THE DRAWING FIGURES

FIG. 1 shows a block diagram of the electron microscope with the detector of back-scattered electrons, the detector of X-ray radiation and the control circuits according to current state of the art.

FIG. 2 shows a data-flow diagram of a basic variant of the equipment for material analysis by a focused electron beam using characteristic X-rays and back-scattered electrons.

FIGS. 3a, 3b and 3c show data-flow diagrams of preferred alternatives where some sections which are shared with the basic variant are left out for clarity.

FIG. 4 shows a block diagram of an electron microscope linked with a processor unit and its peripherals.

FIG. 5 shows a work-flow diagram of a basic variant of a preferred embodiment of the method for material analysis by a focused electron beam using characteristic X-rays and back-scattered electrons.

FIGS. 6, 7 and 8 show work-flow diagrams of other preferred embodiments.

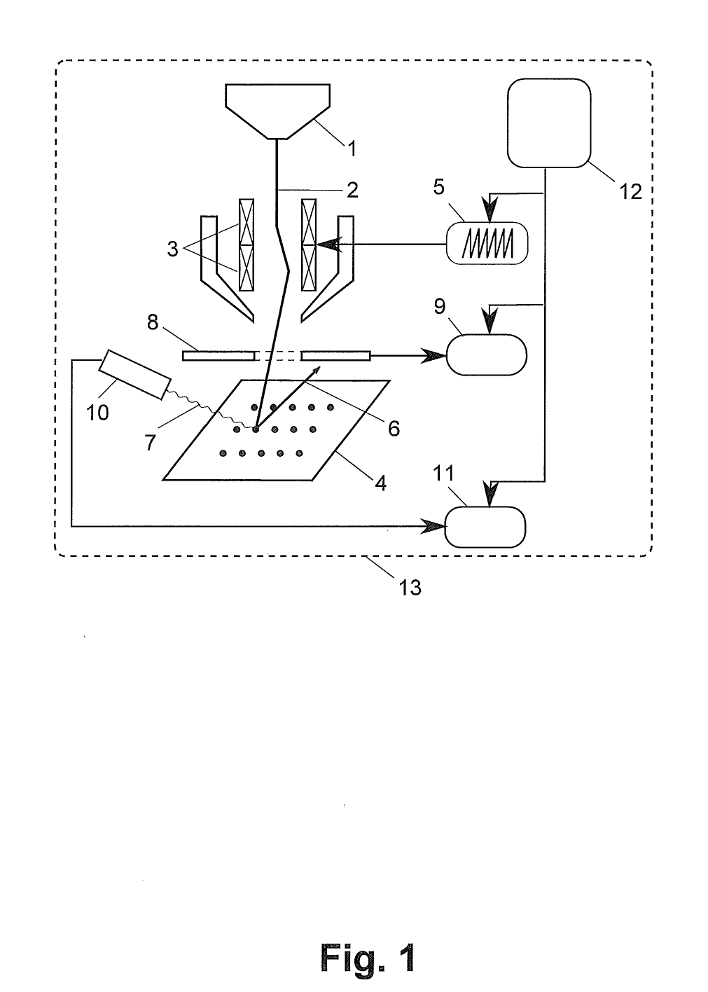

### DETAILED DESCRIPTION OF THE PREFERRED EMBODIMENTS

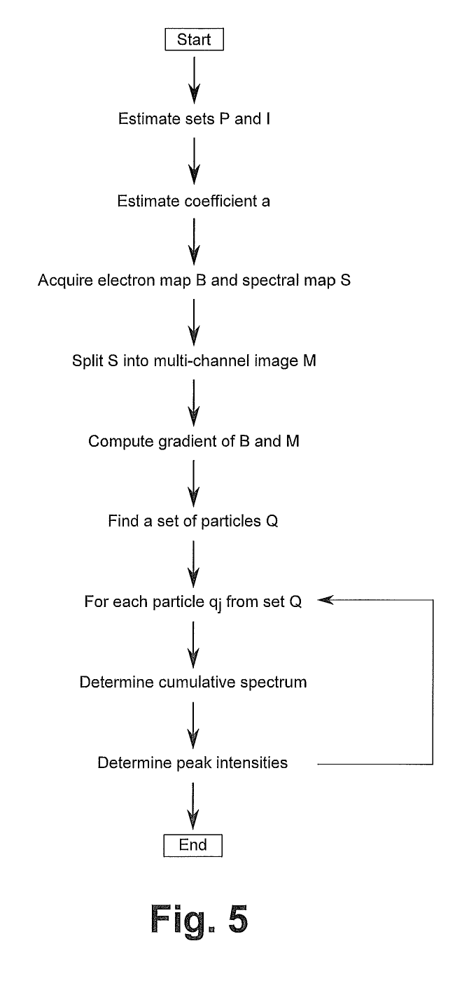

A preferred embodiment of the work-flow of a method of material analysis by a focused electron beam in a scanning electron microscope is depicted in FIG. 5. The method is based on the well-known procedure where at first an expert estimate is used to specify an adequately large set P of chemical elements that might occur in the assayed sample and, for each element pᵢ from the set P, an interval Iᵢ of the energies of the X-ray photons is determined corresponding to one emission line of the element. Next, the focused electron beam is consecutively deflected to points on the assayed sample and, at the points, the intensity of the back-scattered electrons is established in order to create an electron map B and a histogram of the energies of the X-ray radiation emitted at the point is established in order to create a spectral map S. In the new method of the preferred embodiment, an X-ray map Mᵢ is created for each element pᵢ from the set P, where the values Mᵢ(x, y) stored in the map Mᵢ are related to the points on the sample with coordinates (x, y) and correlate with the intensity of X-ray radiation with energy within Iᵢ emitted at the points. The X-ray maps Mᵢ and the electron map B are simultaneously converted into the differential map D, where the values D(x, y) stored in the map D are related to the points on the sample with coordinates (x, y) and correlate with the magnitude of the intensity gradient of the back-scattered electrons and the intensity gradient with energy within the interval Iᵢ at the points. This is followed by image segmentation using a watershed transformation applied to the differential map D with the purpose of searching for particles. The result of the operation is a set Q of particles, where each particle is assigned a sequence number j, and a map R of particle distribution, where values R(x, y) stored in the map R are related to the points on the sample with coordinates (x, y) and correspond to the sequence number of the particle. In the next step, an expert estimate is used to set the value of coefficient a, which value influences the weighting of the border points in the weighted mean, and, by using the weighted mean, a spectrum Xⱼ of X-ray radiation for each particle qⱼ is determined from the spectral map S using the coefficient a where the values Xⱼ(E) are accumulated values of the intensity of X-ray radiation with energy E. Afterwards, the determined values N_{i,j} are subsequently computed as a total number of X-ray events recorded in spectrum Xⱼ with energy within intervals Iᵢ for all elements pᵢ from set P and for all particles qⱼ from set Q.

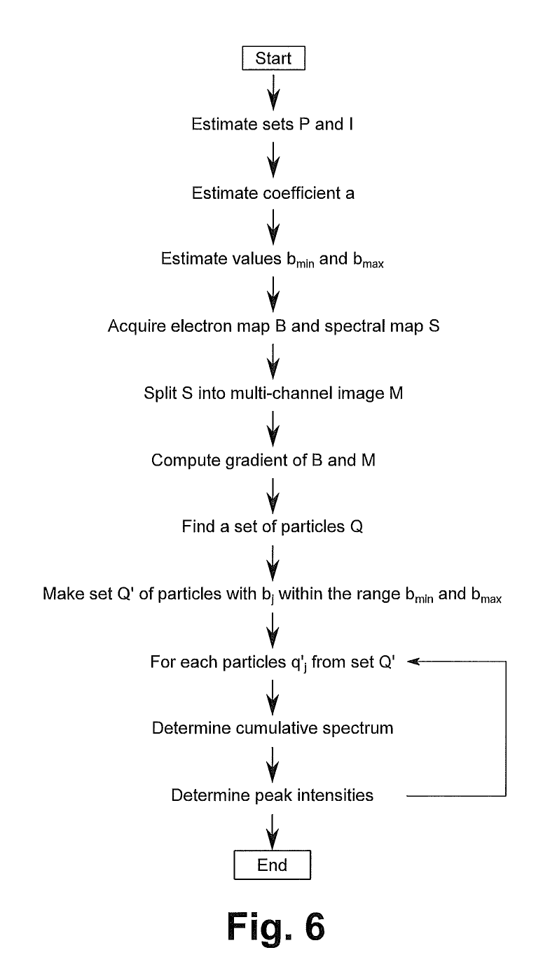

In a further enhancement, the work-flow diagram of which is shown in FIG. 6, an expert estimate is used to set the values of two coefficients bₘᵢₙ and bₘₐₓ, which represent the minimum and maximum expected level of the intensity of the back-scattered electrons in materials, which are subjected to the analysis performed. Next, the medium level of the intensity of the back-scattered electrons bⱼ is determined for each particle qⱼ from the set Q of the particles based on the map R of particle distribution and the electron map B using the median. When the value bⱼ is found in the closed interval between the values bₘᵢₙ and bₘₐₓ, the particle qⱼ is inserted in a new set Q′. Then, the spectrum Xⱼ of the X-ray radiation is established for each particle qⱼ from the new set Q′ by means of the spectral map S using coefficient a. In the end, the determined values N_{i,j} are subsequently computed as a total number of X-ray events recorded in spectrum Xⱼ with energy within intervals Iᵢ for all elements pᵢ from set P and for all particles qⱼ from set Q.

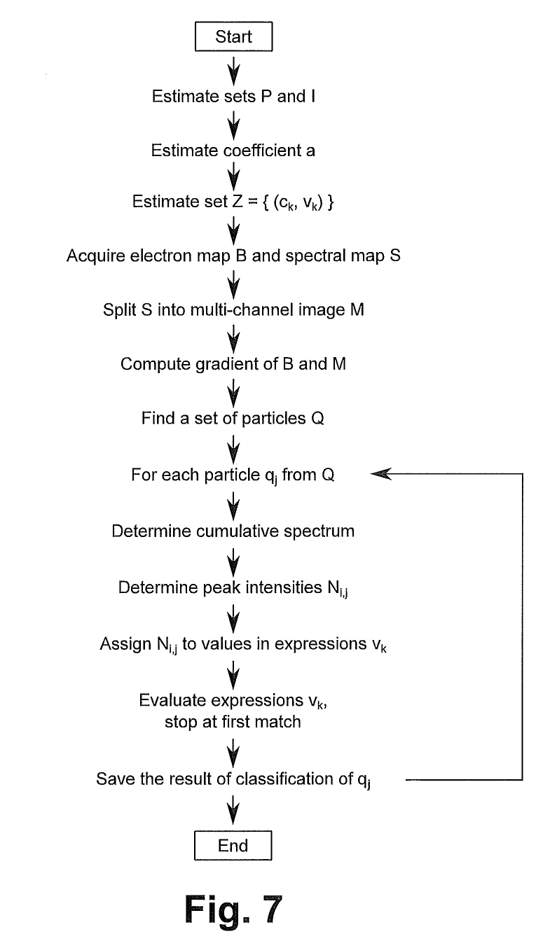

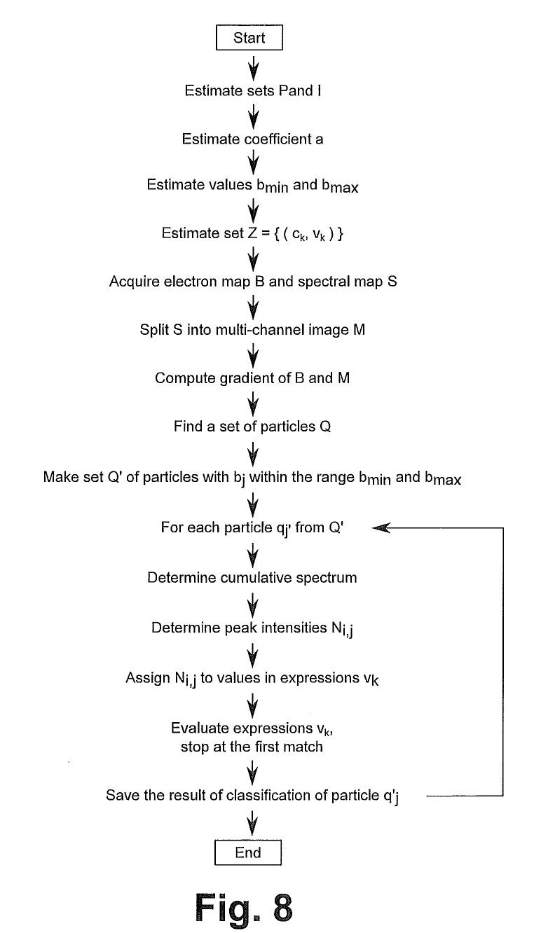

In another preferred embodiment, the work-flow diagram of which is depicted in FIG. 7, a set Z of rules for the classification of materials based on chemical composition is specified by an expert estimate, where Z is a totally ordered set of pairs (cₖ, vₖ) and each class cₖ is assigned a logical expression vₖ consisting of identifiers of variables, arithmetic operators, logical operators, comparison operators and numerical constants. This is followed by specifying a set of variables occurring in the expressions stored in the set Z. For each particle qⱼ from the set Q the determined values N_{i,j} will be assigned to the variables and subsequently the logical value of expressions will be evaluated in order of their appearance in the set Z. The evaluation is stopped on one of two conditions: a) an expression that evaluates to “true” is found or b) all expressions are evaluated to “false”. In case the evaluation has been finished on the first condition, the first class from the top of the set Z whose expression is true is assigned to a set Cⱼ, being a result of classification of particle cₕ. In case of stopping on the second condition, where all expressions are false, the result of the classification of the particle qⱼ is an empty set Cⱼ. This procedure can be applied simultaneously even when the values of the coefficients bₘᵢₙ and bₘₐₓ are set, in this case the mean level of intensity of back-scattered electrons bⱼ is also assigned to a variable occurring in the expressions.

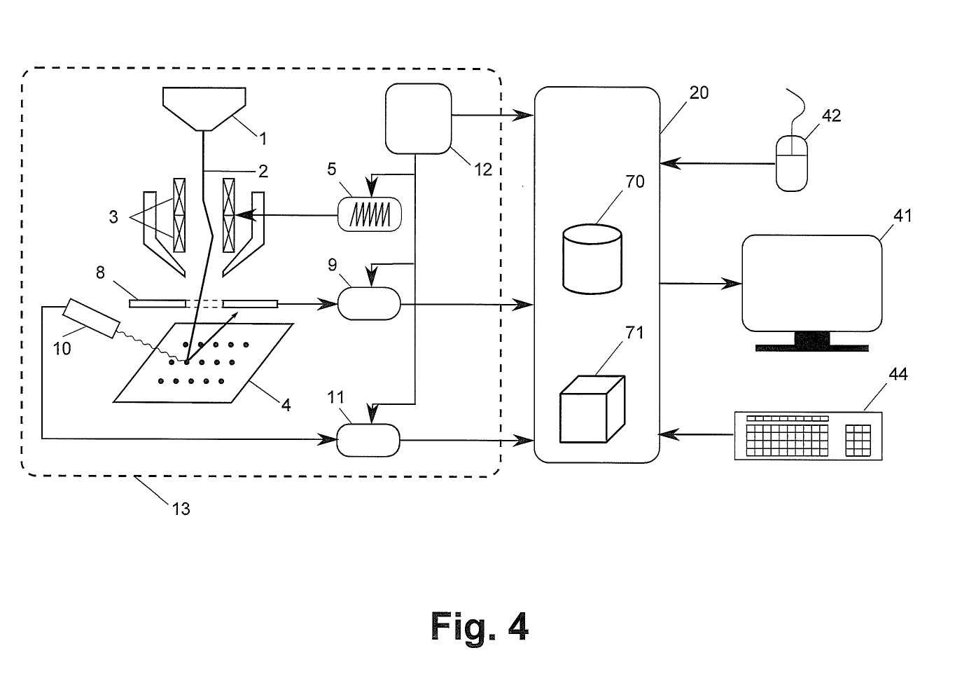

A preferred embodiment of equipment for material analysis by a focused electron beam using characteristic X-rays and back-scattered electrons is schematically depicted in FIG. 4, where some ordinary parts of an electron microscope not directly related to the submitted invention have been omitted from the picture for the sake of clarity. The equipment comprises a scanning electron microscope 13, composed, among other parts, of a electron gun 1 creating a beam of accelerated electrons 2, which is deflected using a pair of deflecting coils 3 so that it consecutively impacts on a sample 4 at various points. The currents through deflecting coils 3 are controlled by scanning circuits 5 that generate the deflecting signal following predefined instructions, most often in a regular rectangular grid. The scanning electron microscope 13 is furnished with a detector 8 of back-scattered electrons and an analog-to-digital converter 9, which converts the analog signal from the detector 8 of back-scattered electrons to a digital format. The equipment is further fitted with an energy-dispersion detector 10 of X-ray radiation and a pulse processor 11, which processes the analog signal from the energy-dispersive detector 10 of X-ray radiation and converts it into a digital format. The deflecting of the beam and the processing of information from all detectors is synchronized by the control unit 12. The output of the analog-to-digital converter 9 and the output of pulse processor 11 are connected to the processing unit 20, where the signal from both types of detectors is stored and processed by following the processing instructions stored in the data storage 70. The processing unit 20 also comprises of memory unit 71 which is employed to keep the intermediate results that are carried between operational blocks and also the final results of the analysis.

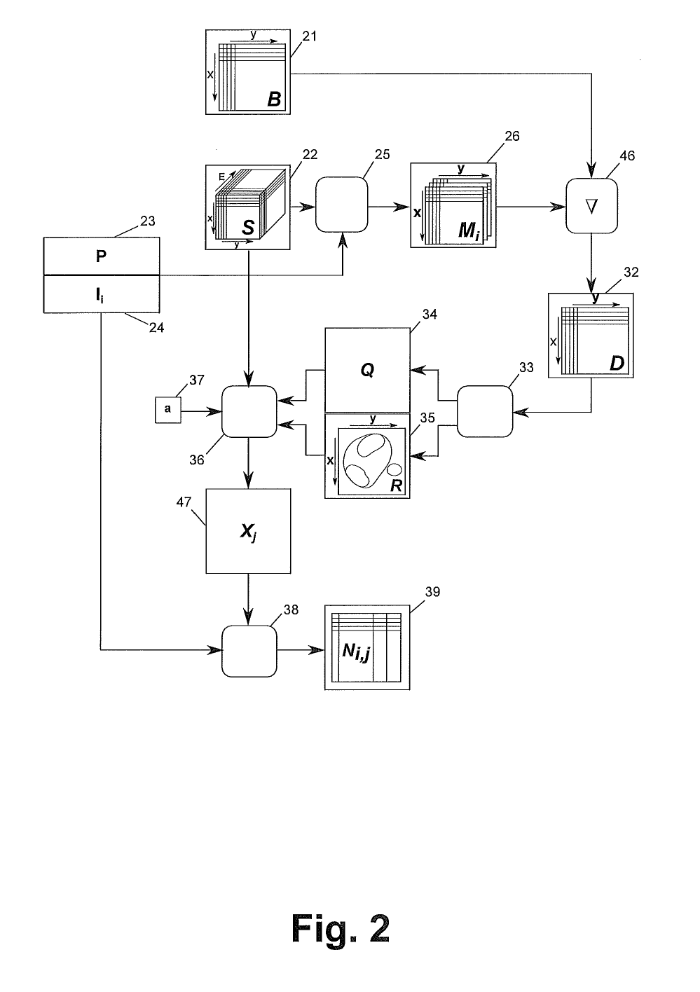

FIG. 2 shows the diagram of operational and memory blocks and their interconnections with respect to the flow of data. The output of the analog-to-digital converter 9 is connected via the first memory 21 to one input of the derivation block 46. The output of the pulse processor 11 is connected to the input of the second memory 22. Its output is connected to the input of the first integration block 25, the second input of which is connected to the output of the fourth memory 24 and third memory 23. The output of the first integration block 25 is connected via the fifth memory 26 to the derivation block 46. The output of the derivation block 46 is connected via the eighth memory 32 to the input of the transformation block 33, whose one output is connected via the ninth memory 34 and tenth memory 35 to inputs of the second integration block 36. The third input of the second integration block 36 is connected to the output of the eleventh memory 37 and its fourth input is connected to the second output of the second memory 22. The output of the second integration block 36 is connected via the seventeenth memory 47 to one input of spectral analyser 38. The spectral analyser 38 is also connected to the third memory 23 and fourth memory 24. The output of spectral analyser 38 is connected to the input of the twelfth memory 39. The whole processing unit 20 is preceded by the input device 44 for entering input values and the pointing device 42 for marking the selected particles.

When an expert estimate is used to set the values of coefficients bₘᵢₙ and bₘₐₓ, the output of the first memory 21 is simultaneously connected to one input of the third integration block 50, the second input of which is connected to the output of the ninth memory 34. The third input of the integration block 50 is connected to the output of the tenth memory 35. The output of the third integration block 50 is then connected to one input of the comparative circuit 51, the second input of which is connected to the output of the thirteenth memory 52. The output of the comparative block 51 is connected via the fourteenth memory 53 to the second input of the second integration block 36.

When specifying a set Z, the output of the twelfth memory 39 is connected to one input of the classifier 60, the second input of which is connected to the output of the fifteenth memory 61. The output of the classifier 60 is connected to the sixteenth memory 62. When both modifications are incorporated, the classifier 60 is fitted with a fourth input connected to the eighteenth memory 54.

In the preferred embodiment, the equipment works in the following way: The control unit 12 generates, following a command from the processing unit 20, scanning instructions which define the sequence of points on the sample 4. The scanning circuits 5 control the current through the deflecting coils 3 so that electron beam 2 gradually impacts on the sample 4 at points according to the scanning instructions. The control unit 12 then communicates with the analog-to-digital converter 9 and the pulse processor 11. The signal from the analog-to-digital converter 9 and the pulse convertor 11 is sent to the processing unit 20, where it is further processed.

The processing unit 20 creates, based on the signal from the detector 8 of back-scattered electrons, an electron map B, which is stored in the first memory 21, containing the intensity of the back-scattered electrons at the points on the sample 4 according to the scanning instructions. The electron map B in this case refers to a two-dimensional field of scalar values, where the two dimensions correspond with the rectangular system of coordinates x and y on the sample 4. Scalar values B(x, y) stored in the electron map B correlate with the intensity of the detected back-scattered electrons at the spot on sample 4 with coordinates (x, y) over time, during which the electron beam remained at this point.

Simultaneously, based on information from the energy-dispersive detector 10 of X-ray radiation, a spectral map S is created in the second memory 22. The spectral map S refers to a three-dimensional field, where the first two dimensions correspond with the coordinates x and y on the sample 4 and the additional third dimension is the ordinal number of the channel corresponding to the narrow interval of the energy of photons E. Scalar values S(x, y, E) stored in the spectral map S correlate with the number of the detected X-ray photons with given energy E at the spot on sample 4 with coordinates (x, y) over time, during which the electron beam remained in this point.

Based on the knowledge of the expected mineralogical or chemical composition of the samples an experienced user will enter, using the input device 44 preceding the processing unit 20, e.g. a keyboard, prior to starting the analysis, a set P of chemical elements where P={pᵢ; i=1, 2, . . . n}, and a set I of the intervals of energies of X-ray radiation, further as set I, where I={Iᵢ; i=1, 2, . . . n}, where n is the number of the elements entered and the interval Iᵢ corresponds to the narrow interval of energies in the surroundings of one of the characteristic emission lines of element pᵢ. The set P is stored in the third memory 23 and the set I is stored in the fourth memory 24 before starting the analysis.

The second memory 22, containing the spectral map S, is linked to the input of the first integration block 25, which will create, for each interval Iᵢ from the set I, one X-ray map Mᵢ according to the following equation.

$${M}_{i} ( x , y ) = {Σ}_{E ∈ {I}_{i}} S ( x , y , E )$$

The X-ray maps Mᵢ are represented by a two-dimensional field, where the two dimensions correspond to the rectangular system of coordinates x and y on the sample. Scalar values Mᵢ(x, y) stored in X-ray maps Mᵢ are proportionate to the intensity of the X-ray radiation characteristic for the element pᵢ in a spot on the sample with coordinates (x, y). Before further processing, the output of the first integration block 25 is stored in the fifth memory 26.

The fifth memory 26, containing the X-ray maps Mᵢ, and the first memory 21, containing the electron map B, are linked to the input of the derivation block 46, which for each X-ray map Mᵢ and the electron B will create a differential map D so that the values D(x, y) are calculated for each spot on the sample with coordinates (x, y) using the multi-channel edge-detection algorithm. The output of the derivation block 46, the differential map D, is stored in the eighth memory 32.

The eighth memory 32, containing the resulting differential map D, is linked to the input of transformation block 33, which performs the image segmentation using the watershed transformation. The result of the segmentation is a set Q of particles found, where Q={qⱼ; j=1, 2, . . . m}, where m is the number of particles found, and a map R of particle distribution, which defines, for each particle qⱼ from the set Q, a set of points (x, y) on the sample 4, which belong to the particle qⱼ. The set Q is stored in the ninth memory 34 and the map R is stored in the tenth memory 35.

The second integration block 36 will read the set Q stored in the ninth memory 34 and the map of particle distribution R stored in the tenth memory 35 and the spectral map S, stored in the second memory 22. In a sequential manner, the accumulated values Xⱼ(E) of the spectrum Xⱼ of X-ray radiation are calculated for each particle qⱼ from the set Q based on the equation below, from all points (x, y), which according to the map R are spatially situated inside the particle qⱼ. The spectra Xⱼ are stored in the seventeenth memory 47.

$${X}_{j} ( E ) = \frac{Σ {w}_{j} ( x , y ) S ( x , y , E )}{Σ {w}_{j} ( x , y )} ; R ( x , y ) = j$$

The weight of contribution wⱼ(x, y) at the point with coordinates (x, y) is calculated from minimum distance dₘᵢₙ(x, y) of point (x, y) from points at the edge of particle qⱼ and coefficient a based on the equations below. Coefficient a is determined by an experienced user prior to starting the analysis based on a knowledge of the nature of the assayed samples and the value is stored in the eleventh memory 37. This step has essential influence on the accuracy of the analysis result and reliability of the following classification. The spectroscopic analysis assumes that the material in the interaction volume, from which the analyzed spectrum originates, is homogeneous. In non-homogeneous materials this precondition is not generally met as owing to the non-negligible size of the interaction volume there is emission of X-ray radiation close to the interface between two particles on both sides of the interface. Using a weighted mean, where the points at the particle boundary have a lower weight than points inside it, can significantly reduce this unwanted phenomenon.

$${w}_{j} ( x , y ) = \frac{{d}_{min} ( x , y )}{a}$$

for dₘᵢₙ(x, y)<a a wⱼ(x, y)=1 f or other values dₘᵢₙ(x, y)

Spectrum Xⱼ, stored in the seventeenth memory 47, enters into the spectral analyzer 38, in which the intensities of the selected characteristic X-ray radiation are established, by computing a total number of X-ray events N_{i,j} that is stored in spectrum Xⱼ for each element pᵢ from a set P. The result of the spectral analysis, intensities are stored in the twelfth memory 39 and is presented to the user on a display device 41 connected to the processing unit 20. The spatial distribution of the particles, the map R of particle distribution, stored in the tenth memory 35, is presented in the form of a two-dimensional image. The user is allowed to use a pointing device 42 preceding the processing unit 20, such as a mouse, to mark in the image one of the particles, and another part of the display device 41 will consequently show the user the peak intensities of the chemical elements stored for the selected particle in the twelfth memory 39.

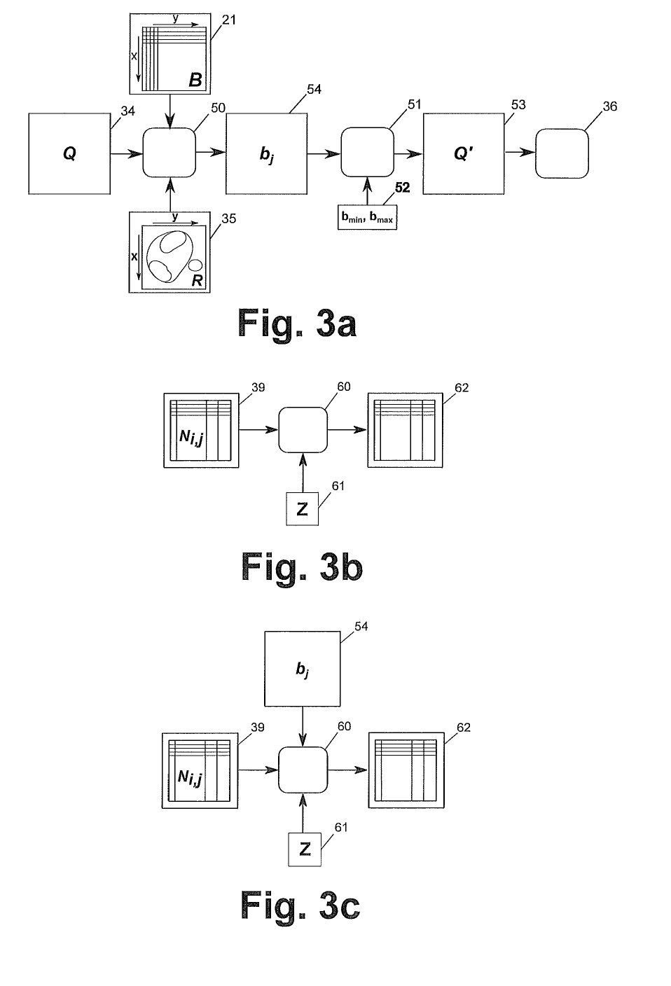

In the second preferred embodiment, the block diagram of which is shown in FIG. 3a, while some of the general parts have been omitted for the sake of greater clarity, the set Q, stored in the ninth memory 34, and the map R of particle distribution, stored in the tenth memory 35, together with the electron map B, stored in the first memory 21, are linked to the input of the third integration block 50, which will calculate, in a sequential manner, from the electron map B using the median, for each particle qⱼ from the set Q, the mean intensity value of back-scattered electrons bⱼ. The values bⱼ are stored to the eighteenth memory 54. The median is calculated from all the values stored in the electron map B, which according to the map R spatially fall within the particle qⱼ. The output of the third integration block 50 is linked to the input of the comparative block 51, where the calculated value bⱼ is compared with the two values bₘᵢₙ and bₘₐₓ. The values bₘᵢₙ and bₘₐₓ are specified by an experienced user using the input device 44 preceding the processing unit 20 prior to starting the analysis based on the knowledge of the nature of the signal of back-scattered electrons in the assayed samples and before starting the analysis the values that are stored in the thirteenth memory 52. The output of the comparative block 51 is a set Q′, where the set Q′ is a subset of the set Q while the set Q′ contains only such particles qⱼ from the set Q, whose value bⱼ falls within the closed interval between the values bₘᵢₙ and bₘₐₓ. The set Q′ is stored in the fourteenth memory 53. In this embodiment, the input of the second integration block 36 is modified so that the particle list is read from the fourteenth memory 53 instead of the ninth memory 34.

In the third preferred embodiment, the block diagram of which is shown in FIG. 3b, while some of the general parts have been omitted for the sake of clarity, the twelfth memory 39, containing peak intensities N_{i,j}, is linked to the input of the classifier 60, which, based on the peak intensities of chemical elements and the set Z will assign the particle qⱼ to either none or one class. The set Z is specified by an experienced user via the input device 44 preceding the processing unit 20 before starting the analysis based on knowledge of the chemical composition of the materials, which may be contained in the assayed sample. The set Z is defined in the form of a totally ordered set of ordered pairs, where Z={(cₖ, vₖ); k=1, 2, . . . n_{C}}, where n_{C} is the number of classes and each class cₖ is assigned a logical expression vₖ, which consists of identifiers of variables, numerical constants, arithmetic operators for negation, addition, multiplication, subtraction and division, operators for comparing two numerical values (equivalence, non-equivalence, greater, greater or equal, lower, lower or equal) and logical operators for negation, logical sum and logical product. Before starting the analysis, set Z is stored in the fifteenth memory 61. The particles are evaluated sequentially, initially the variables are assigned with the values N_{i,j} stored in the twelfth memory 39 for one of the particles (output of the spectral analyzer 38), then for classes cₖ from the set C, where C={cₖ; k=1, 2, . . . n_{C}}, the logical value of expressions vₖ is evaluated in order of their appearance in the set Z. The evaluation is stopped on one of two conditions: a) an expression that evaluates to “true” is found or b) all expressions are evaluated to “false”. In case the evaluation has been finished on the first condition, the first class from the top of the set Z whose expression is true is assigned to a set Cⱼ. In case of stopping on the second condition, where all expressions are false, the set Cⱼ is left empty. The output of the classifier 60 is stored in the sixteenth memory 62 in the form of a table containing the identification number of each particle, values N_{i,j}, i.e. data at the output of the spectral analyzer 38, and the set Cⱼ classes assigned to the particle in the classifier 60. In this preferred embodiment, the result of the analysis is stored in the sixteenth memory 62 and presented to the user on the display device 41 connected to the processing unit 20 in the form of a two-dimensional image, in which the spatial distribution of the particles found is depicted. The user is allowed to use the pointing device 42 preceding the processing unit 20, such as a mouse, to highlight one of the particles in the image, and subsequently in another part of the display device the user is presented with the results of the classification of the selected particle, stored in the sixteenth memory 62, and the values of the elements for the selected particle, stored in the twelfth memory 39.

A fourth preferred embodiment incorporates both modifications described above in the second and third preferred embodiments. The block diagram of the fourth preferred embodiment is shown in FIG. 3c, while some of the general parts have been omitted for the sake of clarity. The eighteenth memory 54 is linked to the input of the classifier 60, which uses the values bⱼ, stored in the eighteenth memory 54, to assist in the classification.

The presented new procedure and equipment are especially suitable for application in mineralogy in the quantitative analysis of ore. In this analysis the assayed sample of an ore is usually crushed to fine particles with a size of the order of units to dozens of micrometers, and is divided using sieves by particle size into several fractions. From each fraction several samples are taken. The samples are then usually mixed with filler and epoxy resin and are left to harden into cylindrical blocks, which are further polished and subsequently covered with a thin conductive layer, typically carbon, to avoid the surface charging. The sample blocks are placed in a scanning electron microscope that collects the data and analyzes the material on their surface. The presented equipment facilitates fully automated analysis of those samples, the results of which are the morphological and chemical properties of the minerals of which the assayed sample is composed and most importantly information on the spatial association of the minerals which in many situations is essential information in terms of determining the physical and chemical properties of ore. The principles, preferred embodiments and mode of operation of the present invention have been described in the foregoing specification. However, the invention which is intended to be protected is not to be construed as limited to the particular embodiments disclosed. The embodiments are therefore to be regarded as illustrative rather than as restrictive. Variations and changes may be made without departing from the spirit of the present invention. Accordingly, it is expressly intended that all such equivalents, variations and changes which fall within the spirit and scope of the present invention as defined in the claims be embraced thereby.

What is claimed is:

1. A method of material analysis by a focused electron beam using characteristic X-rays and back-scattered electrons comprising the steps of:
specifying an adequately large set P of chemical elements which might occur in an assayed sample;
determining an interval of energies of X-ray photons Iᵢ corresponding with an emission line for each element pᵢ from the set P;
deflecting the focused electron beam consecutively into points on the assayed sample;
creating an electron map B, where values B(x, y) stored in the electron map B are related to the points on the assayed sample with coordinates (x, y) and correlate with an intensity of back-scattered electrons generated in these points;
creating a spectral map S by establishing a histogram of energies of X-ray radiation emitted at these points;
creating an X-ray map Mᵢ for each element pᵢ from the set P, where values Mᵢ(x, y) stored in the map Mᵢ are related to the points on the sample with coordinates (x, y) and correlate with intensity of X-ray radiation with energy within interval Iᵢ emitted in these points, the values Mᵢ(x, y) being computed as a total number of X-ray energies recorded in the spectral map S as energies emitted from a point on the sample with coordinates (x, y) and have energy within interval Iᵢ;
converting the X-ray maps Mᵢ and the electron map B into a differential map D using a multi-channel edge-detection algorithm;
performing image segmentation using a watershed transformation applied to the differential map D in order to search for particles to produce a set Q of particles, where each particle is assigned a sequence number j, and a map R of particle distribution, where values R(x, y) stored in the map R are related to the points on the sample with coordinates (x, y) and correspond with the sequence number of the particle;
setting a value of coefficient a and determining spectrum Xⱼ of X-ray radiation for each particle qⱼ from the set Q based on the spectral map S using the coefficient a, where the values Xⱼ(E) are accumulated values of the intensity of X-ray radiation with energy E; and,
computing total number of X-ray events that were recorded in spectrum Xⱼ with energies within intervals Iᵢ corresponding to each element pᵢ from the set P and each particle qⱼ from the set Q in order to get determined values N_{i,j}.

2. The method of claim 1 further comprising the steps of:
setting a value of coefficients bₘᵢₙ and bₘₐₓ after which for each particle qⱼ from the set Q a mean level of the intensity of back-scattered electrons bⱼ is determined based on the map R of particle distribution and the electron map B using the median, where in the case that the value bⱼ is found within the closed interval between the values bₘᵢₙ and bₘₐₓ, the particle qⱼ is inserted in a new set Q′ of particles, after which for each particle qⱼ from the new set Q′ a spectrum Xⱼ of X-ray radiation is determined from the spectral map S using a coefficient; and,
computing total number of X-ray events that were recorded in spectrum Xⱼ with energies within intervals Iᵢ corresponding to each element pᵢ from the set P and each particle qⱼ from the set Q′ in order to get determined values N_{i,j}.

3. The method of claim 1 further comprising the steps of:
specifying a set Z of rules for the classification of materials where Z is a totally ordered set of pairs (cₖ, vₖ) and each class cₖ is assigned a logical expression vₖ consisting of identifiers of variables, arithmetic operators, logical operators, comparison operators and numerical constants;
specifying a set of variables occurring in the expressions stored in the set Z, for each particle qⱼ from the set Q the determined values N_{i,j} are assigned to these variables; and,
evaluating logical value of expressions vₖ in order of their appearance in the set Z and stopping the evaluation on one of two conditions: a) an expression that evaluates to “true” is found or b) all expressions are evaluated to “false,” and wherein if the evaluation has been finished on the first condition, the first class from the top of the set Z whose expression is true, is assigned to a set Cⱼ, being a result of classification of particle qⱼ and if the evaluation has been finished on the second condition, where all expressions are false, the result of the classification of particle qⱼ is an empty set Cⱼ.

4. The method of claim 2 further comprising the steps of:
specifying a set Z of rules for the classification of materials where Z is a totally ordered set of pairs (cₖ, vₖ) and each class cₖ is assigned a logical expression vₖ consisting of identifiers of variables, arithmetic operators, logical operators, comparison operators and numerical constants;
specifying a set of variables occurring in the expressions stored in the set Z, for each particle qⱼ from the set Q′ the determined values N_{i,j} are assigned to these variables; and,
evaluating logical value of expressions vₖ in order of their appearance in the set Z and stopping the evaluation on one of two conditions: a) an expression that evaluates to “true” is found or b) all expressions are evaluated to “false,” and wherein if the evaluation has been finished on the first condition, the first class from the top of the set Z whose expression is true, is assigned to a set Cⱼ, being a result of classification of particle qⱼ and if the evaluation has been finished on the second condition, where all expressions are false, the result of the classification of particle qⱼ is an empty set Cⱼ.

5. Equipment for material analysis by a focused electron beam using characteristic X-rays and back-scattered electrons, the system comprising:
a scanning electron microscope equipped with a detector of back-scattered electrons connected to an input of an analog-to-digital converter and an energy-dispersive detector of X-ray radiation connected to an input of a pulse processor; and,
a processing unit connected to an output of the analog-to-digital converter and an output of the pulse processor, in which initially an adequately large set P of chemical elements which might occur in an assayed sample is specified and for each element pᵢ from the set P an interval of energies of X-ray photons Iᵢ corresponding with one emission line of the element is determined, the processing unit creating an electron map B and establishing a histogram of energies of X-ray radiation emitted to create a spectral map S, after the focused electron beam is consecutively deflected into points on the assayed sample and an intensity of the back-scattered electrons is determined at these points, the processing unit creating an X-ray map Mᵢ for each element pᵢ from a set P, where values Mᵢ(x, y) stored in the map Mᵢ are related to points on the assayed sample with coordinates (x, y) and correlate with intensity of X-ray radiation with energy within interval Iᵢ emitted in these points, in the processing unit, values B(x, y) stored in the electron map B are related to the points on the sample with coordinates (x, y) and correlate with the intensity of back-scattered electrons generated in these points and, in the processing unit, the X-ray maps Mᵢ and the electron map B are converted into a differential map D using a multi-channel edge-detection algorithm, with the processing unit performing image segmentation using a watershed transformation applied to the differential map D in order to search for particles, where the result of the operation is a set Q of particles, where each particle is assigned a sequence number j, and a map R of particle distribution, where values R(x, y) stored in a map R are related to the points on the sample with coordinates (x, y) and correspond with the sequence number of the particle; then the value of coefficient a is set, and for each particle qⱼ from the set Q a spectrum Xⱼ of X-ray radiation is determined based on the spectral map S using the coefficient a, where the values Xⱼ(E) are the accumulated values of the intensity of X-ray radiation with energy E and finally a total number of X-ray events that were recorded in spectrum Xⱼ with energies within intervals Iᵢ is computed corresponding to each element pᵢ from the set P and each particle qⱼ from the set Q in order to get determined values N_{i,j}.

6. The equipment according to claim 5, wherein:
the values of coefficients bₘᵢₙ and bₘₐₓ are set in the processing unit and for each particle qⱼ from the set Q a mean level of intensity of back-scattered electrons bⱼ is determined by the processing unit based on the map R of particle distribution and the electron map B using a median, where in a case that the value bⱼ is found within a closed interval between the values bₘᵢₙ and bₘₐₓ, the particle qⱼ is inserted by the processing unit in a new set Q′ of particles, after which for each particle qⱼ from the new set Q′ a spectrum Xⱼ of X-ray radiation is determined from the spectral map S using a coefficient a.

7. The equipment according to claim 5, wherein:
in the processing unit a set Z is specified of rules for classification of materials where Z is a totally ordered set of pairs (cₖ, vₖ) and each class cₖ is assigned a logical expression vₖ consisting of identifiers of variables, arithmetic operators, logical operators, comparison operators and numerical constants, followed by specifying a set of variables occurring in the expressions stored in the set Z, for each particle qⱼ from the set Q determined values N_{i,j} are assigned to these variables and then a logical value of expressions vₖ are evaluated in order of their appearance in the set Z, the processing unit stopping the evaluation on one of two conditions: a) an expression that evaluates to “true” is found or b) all expressions are evaluated to “false,” and wherein if the evaluation has been finished on the first condition, the first class from the top of the set Z whose expression is true, is assigned to a set Cⱼ, being a result of classification of particle qⱼ and if the evaluation has been finished on the second condition, where all expressions are false, the result of the classification of particle qⱼ is an empty set Cⱼ.

8. The equipment according to claim 6, wherein:
in the processing unit a set Z is specified of rules for classification of materials where Z is a totally ordered set of pairs (cₖ, vₖ) and each class cₖ is assigned a logical expression vₖ consisting of identifiers of variables, arithmetic operators, logical operators, comparison operators and numerical constants, followed by specifying a set of variables occurring in the expressions stored in the set Z, for each particle qᵢ from the set Q′ determined values N_{i,j} are assigned to these variables and then a logical value of expressions vₖ are evaluated in order of their appearance in the set Z, the processing unit stopping the evaluation on one of two conditions: a) an expression that evaluates to “true” is found or b) all expressions are evaluated to “false,” and wherein if the evaluation has been finished on the first condition, the first class from the top of the set Z whose expression is true, is assigned to a set Cⱼ, being a result of classification of particle qⱼ and if the evaluation has been finished on the second condition, where all expressions are false, the result of the classification of particle qⱼ is an empty set Cⱼ.

9. A method of material analysis by a focused electron beam using characteristic X-rays and back-scattered electrons comprising the steps of:
deflecting the focused electron beam consecutively into points on the assayed sample;
creating an electron map B, where values stored in the electron map B are related to the points on the assayed sample and correlate with an intensity of back-scattered electrons generated in these points;
creating an X-ray map Mᵢ for each element pᵢ from a set P, where values stored in the map Mᵢ are related to the points on the sample and correlate with intensity of X-ray radiation with energy emitted in these points;
converting the X-ray maps Mᵢ and the electron map B into a differential map D;
performing image segmentation of the differential map D to produce a set Q of particles, where each particle is assigned a sequence number j, and a map R of particle distribution; and,
computing total number of X-ray events in order to get determined values N_{i,j}.

10. The method of claim 9, wherein the X-ray maps Mᵢ and the electron map B are converted into the differential map D using a multi-channel edge-detection algorithm.

11. The method of claim 9, wherein the image segmentation of the differential map D is performed using a watershed transformation.

12. The method of claim 9 further comprising the steps of:
setting a value of coefficients bₘᵢₙ and bₘₐₓ after which for each particle qⱼ from the set Q a mean level of the intensity of back-scattered electrons bⱼ is determined based on the map R of particle distribution and the electron map B using the median, where in the case that the value bⱼ is found within the closed interval between the values bₘᵢₙ and bₘₐₓ, the particle qⱼ is inserted in a new set Q′ of particles, after which for each particle qⱼ from the new set Q′ a spectrum Xⱼ of X-ray radiation is determined; and,
computing total number of X-ray events that were recorded in spectrum Xⱼ with energies within intervals Iᵢ corresponding to each element pᵢ from the set P and each particle qⱼ from the set Q′ in order to get determined values N_{i,j}.

13. The method of claim 9 further comprising the steps of:
specifying a set Z of rules for the classification of materials where Z is a set of pairs (cₖ, vₖ) and each class cₖ is assigned a logical expression vₖ;
specifying a set of variables occurring in the expressions stored in the set Z, for each particle qⱼ from the set Q the determined values N_{i,j} are assigned to these variables;
evaluating logical value of expressions vₖ and stopping the evaluation on one of two conditions: a) an expression that evaluates to “true” is found or b) all expressions are evaluated to “false,” and wherein if the evaluation has been finished on the first condition, the first class from the top of the set Z whose expression is true, is assigned to a set Cⱼ, being a result of classification of particle qⱼ and if the evaluation has been finished on the second condition, where all expressions are false, the result of the classification of particle qⱼ is an empty set Cⱼ.

14. The method of claim 12 further comprising the steps of:
specifying a set Z of rules for the classification of materials where Z is a set of pairs (cₖ, vₖ) and each class cₖ is assigned a logical expression vₖ;
specifying a set of variables occurring in the expressions stored in the set Z, for each particle qⱼ from the set Q′ the determined values N_{i,j} are assigned to these variables; and,
evaluating logical value of expressions vₖ and stopping the evaluation on one of two conditions: a) an expression that evaluates to “true” is found or b) all expressions are evaluated to “false,” and wherein if the evaluation has been finished on the first condition, the first class from the top of the set Z whose expression is true, is assigned to a set Cⱼ, being a result of classification of particle qⱼ and if the evaluation has been finished on the second condition, where all expressions are false, the result of the classification of particle qⱼ is an empty set Cⱼ.

15. Equipment for material analysis by a focused electron beam using characteristic X-rays and back-scattered electrons, the system comprising:
a scanning electron microscope equipped with a detector of back-scattered electrons connected to an input of an analog-to-digital converter and an energy-dispersive detector of X-ray radiation connected to an input of a pulse processor; and,
a processing unit connected to an output of the analog-to-digital converter and an output of the pulse processor, the processing unit creating an electron map B, after the focused electron beam is consecutively deflected into points on the assayed sample and an intensity of the back-scattered electrons is determined at these points, the processing unit creating an X-ray map Mᵢ for each element pᵢ from a set P, and, in the processing unit, the X-ray maps Mᵢ and the electron map B are converted into a differential map D using a multi-channel edge-detection algorithm, with the processing unit performing image segmentation of the differential map D in order to search for particles, where the result of the operation is a set Q of particles, and a map R of particle distribution, and for each particle qⱼ from the set Q a spectrum Xⱼ of X-ray radiation is determined in order to get determined values N_{i,j}.

16. The equipment according to claim 15, wherein:
the values of coefficients bₘᵢₙ and bₘₐₓ are set in the processing unit and for each particle qⱼ from the set Q a mean level of intensity of back-scattered electrons bⱼ is determined by the processing unit based on the map R of particle distribution and the electron map B using a median, where in a case that the value bⱼ is found within a closed interval between the values bₘᵢₙ and bₘₐₓ, the particle qⱼ is inserted by the processing unit in a new set Q′ of particles, after which for each particle qⱼ from the new set Q′ a spectrum Xⱼ of X-ray radiation is determined.

17. The equipment according to claim 15, wherein:
in the processing unit a set Z is specified of rules for classification of materials where Z is a totally ordered set of pairs (cₖ, vₖ) and each class cₖ is assigned a logical expression vₖ and for each particle qⱼ from the set Q determined values N_{i,j} are assigned to these variables and then a logical value of expressions vₖ are evaluated in order of their appearance in the set Z, the processing unit stopping the evaluation on one of two conditions: a) an expression that evaluates to “true” is found or b) all expressions are evaluated to “false,” and wherein if the evaluation has been finished on the first condition, the first class from the top of the set Z whose expression is true, is assigned to a set Cⱼ, being a result of classification of particle qⱼ and if the evaluation has been finished on the second condition, where all expressions are false, the result of the classification of particle qⱼ is an empty set Cⱼ.

18. The equipment according to claim 16, wherein:
in the processing unit a set Z is specified of rules for classification of materials where Z is a totally ordered set of pairs (cₖ, vₖ) and each class cₖ is assigned a logical expression vₖ consisting of identifiers of variables, arithmetic operators, logical operators, comparison operators and numerical constants, followed by specifying a set of variables occurring in the expressions stored in the set Z, for each particle qⱼ from the set Q′ determined values N_{i,j} are assigned to these variables and then a logical value of expressions vₖ are evaluated in order of their appearance in the set Z, the processing unit stopping the evaluation on one of two conditions: a) an expression that evaluates to “true” is found or b) all expressions are evaluated to “false,” and wherein if the evaluation has been finished on the first condition, the first class from the top of the set Z whose expression is true, is assigned to a set Cⱼ, being a result of classification of particle qⱼ and if the evaluation has been finished on the second condition, where all expressions are false, the result of the classification of particle qⱼ is an empty set Cⱼ.
